(19) United States
(12) Patent Application Publication
(10) Pub. No.: US 2023/0072892 A1
(43) Pub. Date: Mar. 9, 2023

(54) RADIO FREQUENCY EXTRACTOR

(71) Applicant: SAMSUNG ELECTRO-MECHANICS CO., LTD., Suwon-si (KR)

(72) Inventors: Sung Tae KIM, Suwon-si (KR); Bo Hyun SEO, Suwon-si (KR); Tae Seok KO, Suwon-si (KR); Sang Heon HAN, Suwon-si (KR)

(73) Assignee: SAMSUNG ELECTRO-MECHANICS CO., LTD., Suwon-si (KR)

(21) Appl. No.: 17/669,597

(22) Filed: Feb. 11, 2022

(30) Foreign Application Priority Data
Aug. 27, 2021 (KR) 10-2021-0114078

(51) Int. Cl. H03H 9/54; H03H 9/00

(52) U.S. Cl. CPC H03H 9/547; H03H 9/0014

(57) ABSTRACT

A radio frequency (RF) extractor includes: a first bandpass filter electrically connected between a shared antenna port and a first RF port, disposed in a first chip, and having a first passband; a second bandpass filter electrically connected between the shared antenna port and a second RF port, and disposed in a second chip, and having a second passband; a first notch filter electrically connected to the shared antenna port, disposed in the first chip, and having a first stopband partially overlapping the first passband; and a second notch filter electrically connected to the shared antenna port, disposed in the second chip, and having a second stopband partially overlapping the second passband.

### CROSS-REFERENCE TO RELATED APPLICATIONS

This application claims the benefit under 35 USC 119(a) of Korean Patent Application No. 10-2021-0114078 filed on Aug. 27, 2021, in the Korean Intellectual Property Office, the entire disclosure of which is incorporated herein by reference for all purposes.

### BACKGROUND

### 1. Field

The following description relates to a radio frequency (RF) extractor.

### 2. Description of Related Art

In general, electronic devices providing a plurality of communications are being optimized by reducing the number of antennas, and by reducing the size and/or the number of components (e.g., filters) for implementing the plurality of communications in the electronic devices.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a radio frequency (RF) extractor includes: a first bandpass filter electrically connected between a shared antenna port and a first RF port, disposed in a first chip, and having a first passband; a second bandpass filter electrically connected between the shared antenna port and a second RF port, and disposed in a second chip, and having a second passband; a first notch filter electrically connected to the shared antenna port, disposed in the first chip, and having a first stopband partially overlapping the first passband; and a second notch filter electrically connected to the shared antenna port, disposed in the second chip, and having a second stopband partially overlapping the second passband.

The first and second notch filters may be electrically connected to each other in series between the shared antenna port and a third RF port.

The RF extractor may further include an impedance matching element electrically connected between the first and second notch filters.

The impedance matching element may have a third passband.

The first chip may include a plurality of first bulk acoustic resonators, and the second chip may include a plurality of second bulk acoustic resonators.

The first bandpass filter and the first notch filter may include one portion and another portion of the plurality of first bulk acoustic resonators, respectively. The second bandpass filter and the second notch filter may include one portion and another portion of the plurality of second bulk acoustic resonators, respectively.

Either one or both of the first bandpass filter and the first notch filter may further include a first inductor electrically connected between at least one of the plurality of first bulk acoustic resonators and a ground in series. Either one or both of the second bandpass filter and the second notch filter may further include a second inductor electrically connected between at least one of the plurality of second bulk acoustic resonators and the ground in series.

A difference between a lowest frequency of the first stopband and a lowest frequency of the first passband, a difference between a lowest frequency of the second stopband and a lowest frequency of the second passband, a difference between a highest frequency of the first stopband and a highest frequency of the first passband, and a difference between a highest frequency of the second stopband and a highest frequency of the second passband may each be less than 100 MHz. A difference between a higher frequency, among the highest frequency of the first stopband and the highest frequency of the first passband, and a lower frequency, among the lowest frequency of the second stopband and the lowest frequency of the second passband, may exceed 100 MHz.

Each of the first passband and the first stopband may cover at least a portion of a frequency range of 1559 MHz to 1606 MHz. Each of the second passband and the second stopband may cover at least a portion of a frequency range of 2400 MHz to 2481 MHz.

A bandwidth of the first stopband may be wider than a bandwidth of the first passband. A bandwidth of the second stopband may be wider than a bandwidth of the second passband.

In another general aspect, a radio frequency (RF) extractor includes: a first bandpass filter electrically connected between a shared antenna port and a first RF port and having a first passband; a second bandpass filter electrically connected between the shared antenna port and a second RF port and having a second passband; a first notch filter electrically connected between the shared antenna port and a third RF port and having a first stopband partially overlapping the first passband; and a second notch filter electrically connected between the shared antenna port and the third RF port and having a second stopband partially overlapping the second passband. The first and second notch filters are electrically connected to each other between the shared antenna port and the third RF port in series.

The RF extractor may further include an impedance matching element electrically connected between the first and second notch filters.

The impedance matching element may have a third passband.

The first bandpass filter and the first notch filter may include one portion and another portion of a plurality of first bulk acoustic resonators, respectively. The second bandpass filter and the second notch filter may include one portion and another portion of a plurality of second bulk acoustic resonators, respectively.

A difference between a lowest frequency of the first stopband and a lowest frequency of the first passband, a difference between a lowest frequency of the second stopband and a lowest frequency of the second passband, a difference between a highest frequency of the first stopband and a highest frequency of the first passband, and a difference between a highest frequency of the second stopband and a highest frequency of the second passband may each be less than 100 MHz. A difference between a higher frequency, among the highest frequency of the first stopband and the highest frequency of the first passband, and a lower frequency, among the lowest frequency of the second stopband and the lowest frequency of the second passband, may exceed 100 MHz.

Each of the first passband and the first stopband may cover at least a portion of a frequency range of 1559 MHz to 1606 MHz. Each of the second passband and the second stopband may cover at least a portion of a frequency range of 2400 MHz to 2481 MHz. A bandwidth of the first stopband may be wider than a bandwidth of the first passband. A bandwidth of the second stopband may be wider than a bandwidth of the second passband.

In another general aspect, an electronic device includes: a first chip including a first bandpass filter electrically connected between a shared antenna port and a first RF port, the first bandpass filter having a first passband corresponding to a GPS communication standard, and a first notch filter electrically connected to the shared antenna port and having a first stopband partially overlapping the first passband; and a second chip including a second bandpass filter electrically connected between the shared antenna port and a second RF port, the second bandpass filter having a second passband corresponding to a W-Fi communication standard, and a second notch filter electrically connected to the shared antenna port and having a second stopband partially overlapping the second passband.

The electronic device may further include an impedance matching element having a third passband and connected between the first and second notch filters. The first and second notch filters may be electrically connected to each other between the shared antenna port and a third RF port.

The first bandpass filter and the first notch filter may include portions of a plurality of first bulk acoustic resonators, respectively. The second bandpass filter and the second notch filter may include portions of a plurality of second bulk acoustic resonators, respectively.

A bandwidth of the first stopband may be wider than a bandwidth of the first passband. A bandwidth of the second stopband may be wider than a bandwidth of the second passband.

Other features and aspects will be apparent from the following detailed description, the drawings, and the claims.

### BRIEF DESCRIPTION OF DRAWINGS

FIGS. 1A to 1D are block diagrams illustrating an RF extractor, according to examples.

FIGS. 2A and 2B are block diagrams illustrating filtering of filters included in an RF extractor, according to examples.

FIGS. 3A and 3B are circuit diagrams illustrating an RF extractor, according to examples, in which filters each include a plurality of bulk acoustic resonators.

FIGS. 4A to 4C are graphs illustrating bands of filters included in an RF extractor, according to an example.

FIG. 5 is a perspective view illustrating an RF extractor, according to an example.

FIG. 6A is a plan view illustrating a detailed structure of a bulk acoustic resonator that may be included in an RF extractor, according to an example.

FIG. 6B is a cross-sectional view taken along line I-I′ of FIG. 6A.

FIG. 6C is a cross-sectional view taken along line II-II′ of FIG. 6A. FIG. 6D is a cross-sectional view taken along line III-III′ of FIG. 6A.

FIGS. 6E and 6F are cross-sectional views illustrating a structure electrically connecting the inside and the outside of a chip that may be included in an RF extractor, according to examples.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

Herein, it is to be noted that use of the term “may” with respect to an embodiment or example, e.g., as to what an embodiment or example may include or implement, means that at least one embodiment or example exists in which such a feature is included or implemented while all examples and examples are not limited thereto.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

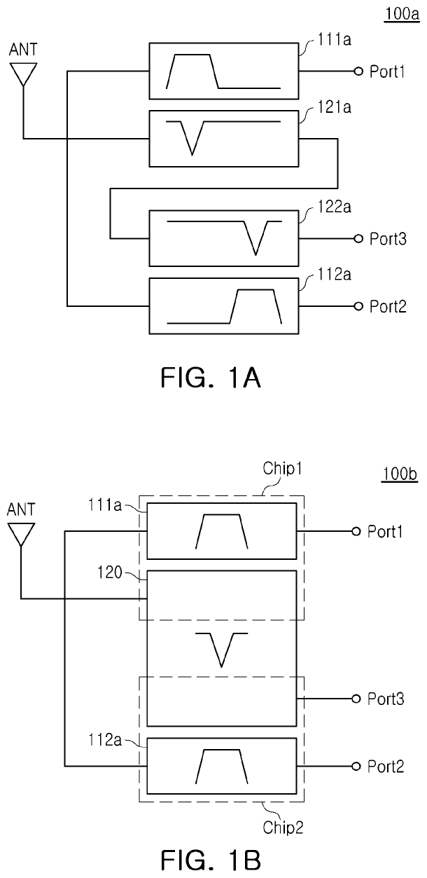

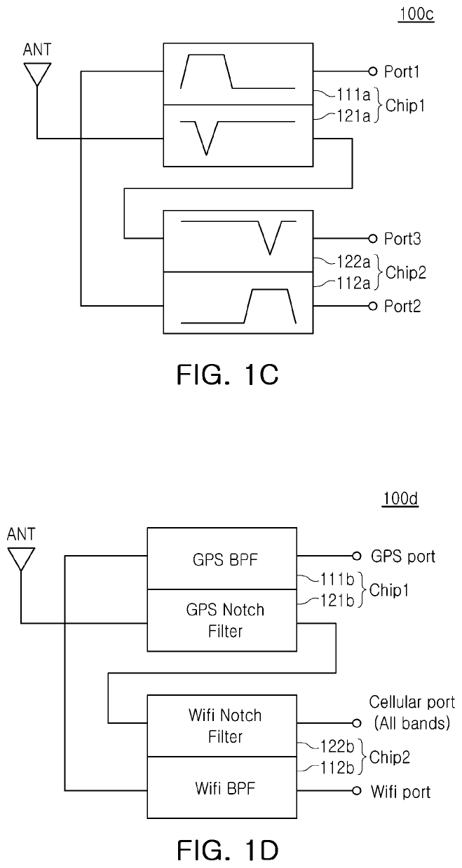

FIGS. 1A to 1D are block diagrams illustrating an RF extractor, according to examples.

Referring to FIG. 1A, an RF extractor 100a may include, for example, a first bandpass filter 111a, a second bandpass filter 112a, a first notch filter 121a, and a second notch filter 122a.

The first bandpass filter 111a may be electrically connected between a shared antenna port ANT and a first RF port Port1, and may have a first passband (e.g., a frequency band according to the GPS communication standard).

The second bandpass filter 112a may be electrically connected between the shared antenna port ANT and a second RF port Port2, and may have a second passband (e.g., a frequency band according to the Wi-Fi communication standard).

For example, the shared antenna port ANT and the first and second RF ports Port1 and Port2 may be respectively electrically connected and/or coupled to external electrical connection structures of the RF extractor 100a, such as a terminal, a via, a connector, a coupler, a solder ball, bumps, and lands.

Since the first bandpass filter 111a may have the first passband, the first bandpass filter 111a may pass a radio frequency (RF) signal of a frequency belonging to the first passband, among the RF signals passing through the shared antenna port ANT, and may block an RF signal or noise of a frequency not belonging to the first passband, among the RF signals passing through the shared antenna port ANT. Accordingly, a component (e.g., RFIC, transceiver) that may be electrically connected to the first RF port Port1 may perform a first communication according to the first communication standard corresponding to the first passband, on the RF signal passing through the first bandpass filter 111a.

Since the second bandpass filter 112a may have the second passband, the second bandpass filter 112a may pass an RF signal of a frequency belonging to the second passband, among the RF signals passing through the shared antenna port ANT, and may block an RF signal or noise of a frequency that does not belong to the second passband among the RF signals passing through the shared antenna port ANT. Therefore, a component (e.g., RFIC, transceiver) that may be electrically connected to the second RF port (Port2) may perform a second communication according to a second communication standard corresponding to the second passband, on the RF signal passing through the second bandpass filter 112a.

The shared antenna may be electrically connected to the shared antenna port ANT, and may be configured to have a wide bandwidth to cover both the first and second passbands. Since the total number of antennas of the electronic device in which the RF extractor 100a is disposed according to an example may be reduced, the electronic device may have a size reduced by as much as the space occupied by an antenna and a peripheral structure (e.g., an electromagnetic shielding structure, an impedance matching structure, an RF signal transmission line, or the like) of the antenna, or may use other electronic device components occupying as much as the occupied space, or may further improve the performance of the remaining antenna.

The first notch filter 121a may have a first stopband that is electrically connected to the shared antenna port ANT and has at least a portion overlapping at least a portion of the first passband.

The second notch filter 122a may have a second stopband that is electrically connected to the shared antenna port ANT and has at least a portion overlapping at least a portion of the second passband.

The first notch filter 121a may block an RF signal of a frequency belonging to a first cut-off band, among RF signals passing through the shared antenna port ANT, and may pass an RF signal of a frequency that does not belong to the first cut-off band, among the RF signals passing through the shared antenna port ANT. The second notch filter 122a may block an RF signal of a frequency belonging to a second cut-off band, among RF signals passing through the shared antenna port ANT, and may pass an RF signal of a frequency that does not belong to the second cut-off band, among the RF signals passing through the shared antenna port ANT.

At least a portion of the first and second stopbands may overlap at least a portion of the first and second passbands. Thus, at least a portion of frequencies not belonging to the first and second passbands among the RF signals passing through the shared antenna port (ANT) may be used for the third communication according to a third communication standard (3G, 4G, 5G cellular communications).

In addition, the RF signal of the third frequency band that may correspond to the third communication standard may be blocked by the first and second bandpass filters 111a and 112a, and the RF signal of the first and second passbands may be blocked by the first and second notch filters 121a and 122a. Therefore, a component (e.g., RFIC, transceiver) that may be electrically connected to the first, second, and third RF ports Port1, Port2, and Port3 may efficiently improve the performance (e.g., gain, power consumption) of the first, second, and third communications and that may comply with the first, second, and third communication standards (e.g., linearity characteristics) more efficiently may suppress interference, since the first, second and third communications may be respectively suppressed from interfering/colliding with each other.

Therefore, the wide bandwidth of the shared antenna that may be electrically connected to the shared antenna port (ANT) may be used more efficiently in the electronic device. Since the electronic device efficiently uses the wide bandwidth of the shared antenna, the total number of antennas of the electronic device may be effectively reduced, and the electronic device may have a size reduced by as much as the space occupied by an antenna and the surrounding structure (e.g., electromagnetic shielding structure, impedance matching structure, RF signal transmission line, or the like) of the antenna, or may use other electronic device components occupying as much as the occupied space or may further improve the performance of the remaining antenna.

Referring to FIG. 1A, the first and second notch filters 121a and 122a may be electrically connected in series between the shared antenna port ANT and the third RF port Port3.

Accordingly, the total number of RF ports may be reduced. As the total number of RF ports decreases, the total size of the electromagnetic shielding structure, the impedance matching structure, and/or the RF signal transmission line may also be reduced. Therefore, the RF extractor 100a may have a further reduced size while efficiently using a wide bandwidth of a shared antenna that may be electrically connected to the shared antenna port ANT.

In addition, since an RF signal of a frequency belonging to at least one of the first and second stopbands may be blocked by one of the first and second notch filters 121a and 122a, a component (e.g., RFIC, transceiver) that may be electrically connected to the third RF port Port3 may smoothly perform a third communication according to the third communication standard (3G, 4G, 5G cellular communications).

Referring to FIGS. 1B and 10, RF extractors 100b and 100c according to examples may include a first bandpass filter 111a, a second bandpass filter 112a, and a notch filter 120.

A portion of the notch filter 120 and the first bandpass filter 111a may be disposed in a first chip Chip1, and the other portion of the notch filter 120 and the second bandpass filter 112a may be disposed in a second chip Chip2.

The portion of the notch filter 120 disposed in the first chip Chip 1 may be a first notch filter 121a, and the other portion of the notch filter 120 disposed in the second chip Chip 2 may be a second notch filter 122a. For example, the first chip Chip1 may include the first bandpass filter 111a and the first notch filter 121a, and the second chip Chip2 may include the second bandpass filter 112a and the second notch filter 122a.

For example, each of the first and second chips Chip1 and Chip2 may be a micro-electromechanical system (MEMS) chip or a semiconductor chip, and may be manufactured separately from a stacked structure in which a plurality of conductive layers and a plurality of insulating layers are alternately stacked, like a PCB, and may be disposed in the stacked structure. The structure (e.g., piezoelectric element) included in the first and second chips Chip1 and Chip2 may be implemented smaller than, more precise than or further different from those in the stacked structure. Accordingly, the first bandpass filter 111a, the second bandpass filter 112a, and the notch filter 120 included in at least one of the first and second chips Chip1 and Chip2 may have improved performance (e.g.: attenuation performance, insertion loss, or the like) more efficiently.

As the total number of chips is included in the RF extractors 100b and 100c is smaller, the size of the RF extractors 100b and 100c may be more advantageously reduced, and the RF extractors 100b and 100c may be implemented more cheaply.

The band of each of the first bandpass filter 111a, the second bandpass filter 112a, and the notch filter 120 may be formed based on at least one resonant frequency, and since the resonant frequency deviation in each of the first and second chips Chip1 and Chip2 is reduced, each of the first and second chips Chip1 and Chip2 may be implemented more efficiently.

For example, when the deviation of the resonance frequencies included in each of the first and second chips Chip1 and Chip2 is relatively small, the deviation of kt² (electromechanical coupling factor), which is a physical characteristic of the bulk acoustic resonator, may be small. Therefore, the relatively small deviation of the resonant frequency may be implemented by the thickness deviation of the electrode and/or the protective layer, the thickness deviation of the electrode and/or the protective layer does not act as a limit in increasing the number of filters included in the first and second chips Chip1 and Chip2, and the performance (e.g., attenuation performance, insertion loss, or the like) of the filter may be efficiently secured.

For example, if the deviation of the resonant frequency included in each of the first and second chips Chip1 and Chip2 is relatively large, the kt² deviation may be large, and thus, the large deviation of resonant frequency may be implemented by a change in the design or a change in a material of the piezoelectric layer, substrate, and cavity. In this case, the design change or material change may act differently from the thickness deviation of the electrode and/or the protective layer.

Since at least a portion of the first passband and at least a portion of the first stopband may overlap each other, the first chip Chip1 may efficiently include the first bandpass filter 111a and the first notch filter 121a. Since at least a portion of the second passband and at least a portion of the second stopband may overlap each other, the second chip Chip2 may efficiently include the second bandpass filter 112a and the second notch filter 122a.

Accordingly, the RF extractors 100b and 100c may be reduced or inexpensively implemented while securing good filter performance (e.g., attenuation performance, insertion loss, or the like).

Referring to FIG. 1D, an RF extractor 100d may include a first bandpass filter 111b, a second bandpass filter 112b, a first notch filter 121b, and a second notch filter 122b.

The first bandpass filter 111b may have a first passband corresponding to GPS and may be electrically connected to a GPS port belonging to a GPS communication path. The second bandpass filter 112b may have a second passband corresponding to Wi-Fi, and may be electrically connected to a Wi-Fi port belonging to a Wi-Fi communication path.

The first notch filter 121b may have a first stopband corresponding to the GPS and may be electrically connected to a cellular port belonging to a cellular communication path. The second notch filter 122b may have a second stopband corresponding to Wi-Fi, and may be electrically connected to a cellular port belonging to a cellular communication path.

Communication standards corresponding to the first, second and third communications are not limited to GPS, Wi-Fi, and cellular communications, and depending on the design, may also correspond to other communication standards such as WCDMA, PCS, Bluetooth, WiMAX, Ev-DO, HSPA+, HSDPA+, HSUPA+, EDGE, GSM, GPRS, CDMA, TDMA, or DECT.

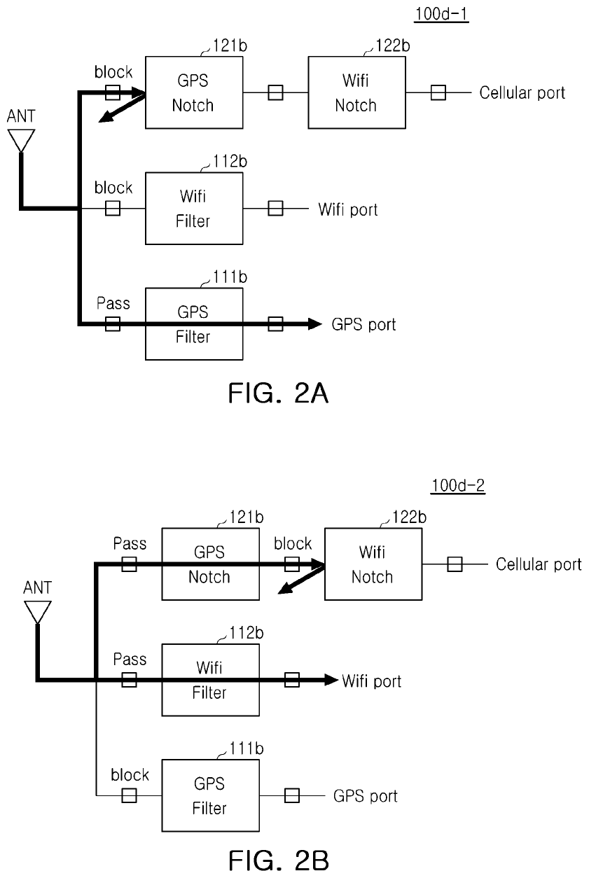

FIGS. 2A and 2B are block diagrams illustrating filtering of filters included in an RF extractor, according to an example.

Referring to FIG. 2A, an RF extractor 100d-1 may pass an RF signal of a first frequency corresponding to GPS to a GPS port through a first bandpass filter 111b, and may block the RF signal through a second bandpass filter 112b and a first notch filter 121b.

Referring to FIG. 2B, an RF extractor 100d-2 may pass an RF signal of a second frequency corresponding to Wi-Fi to a Wi-Fi port through a second bandpass filter 112b, and may block the RF signal through a first bandpass filter 111b and a second notch filter 122b.

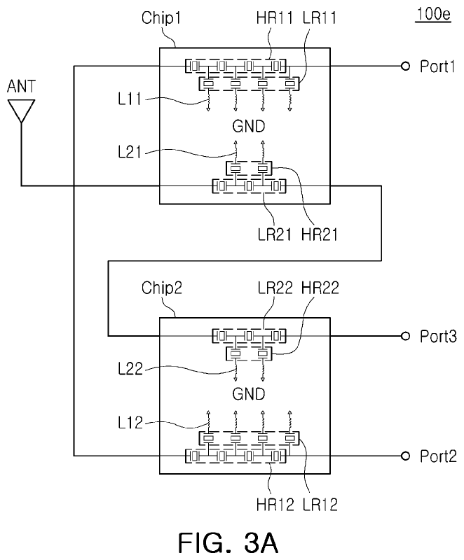

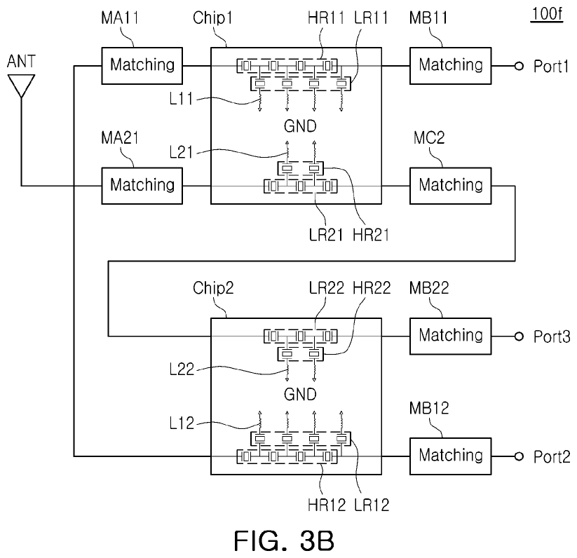

FIGS. 3A and 3B are circuit diagrams illustrating an RF extractor, according to examples, in which filters each include a plurality of bulk acoustic resonators.

Referring to FIG. 3A, an RF extractor 100e may include first and second chips Chip1 and Chip2, and the first chip Chip1 may include a plurality of first bulk acoustic resonators HR11, LR11, HR21 and LR21 and/or first inductors L11 and L21, and the second chip Chip2 may include a plurality of second bulk acoustic resonators HR12, LR12, HR22 and LR22 and/or second inductors L12 and L22.

The first bulk acoustic resonators HR11 may be connected to each other in series. The first bulk acoustic resonators LR11 may be connected to each other in series. The first bulk acoustic resonators HR21 may be connected to each other in series. The first bulk acoustic resonators LR21 may be connected to each other in series.

The second bulk acoustic resonators HR12 may be connected to each other in series. The second bulk acoustic resonators LR12 may be connected to each other in series. The second bulk acoustic resonators HR22 may be connected to each other in series. The second bulk acoustic resonators LR22 may be connected to each other in series.

The first bandpass filter may include some HR11 and LR11 of the plurality of first bulk acoustic resonators, and may further include a portion L11 of the first inductors. The first notch filter may include other portions HR21 and LR21 of the plurality of first bulk acoustic resonators, and may further include another portion L21 of the first inductors.

The second bandpass filter may include some HR12 and LR12 of the plurality of second bulk acoustic resonators and may further include a portion L12 of the second inductors. The second notch filter may include other portions HR22 and LR22 of the plurality of second bulk acoustic resonators, and may further include another portion L22 of the second inductors.

Some HR11 and LR11 of the plurality of first bulk acoustic resonators, other portions HR21 and LR21 thereof, and some HR12 and LR12 of the plurality of second bulk acoustic resonators and other portions HR22 and LR22 thereof may respectively have a structure in which at least one series of bulk acoustic resonators and at least one shunt bulk acoustic resonator are connected in a ladder-type or lattice-type manner.

Electrical connection nodes between bulk acoustic resonators may be implemented as a metal layer including a material having a relatively low resistivity, such as gold (Au), a gold-tin (Au—Sn) alloy, copper (Cu), a copper-tin (Cu—Sn) alloy, aluminum (Al), an aluminum alloy, and the like, but the material of the metal layer is not limited to the foregoing examples. Each of the bulk acoustic resonators may be a film bulk acoustic resonator (FBAR) or a solidly mounted resonator (SMR) type resonator, but is not limited thereto.

Each of the at least one series of acoustic resonators HR11, HR12, LR21 and LR22 and the at least one shunt acoustic resonator (LR11, LR12, HR21, HR22) may convert electrical energy of an RF signal into mechanical energy and may mechanical energy to electrical energy of an RF signal, by a piezoelectric characteristic. As the frequency of the RF signal becomes closer to the resonant frequency of the bulk acoustic resonator, the energy transfer rate between the plurality of electrodes may be significantly increased, and as the frequency of the RF signal becomes closer to the anti-resonant frequency of the bulk acoustic resonator, the energy transfer rate between the plurality of electrodes may be significantly reduced. The anti-resonant frequency of the bulk acoustic resonator may be higher than the resonant frequency of the bulk acoustic resonator.

At least one series of bulk acoustic resonators HR11, HR12, LR21 and LR22 are electrically connected in series between one of the first, second and third RF ports Port1, Port2, and Port3 and the shared antenna port ANT. As the frequency of the RF signal becomes closer to the resonant frequency, the pass rate of the RF signal between ports may be increased, and as the frequency of the RF signal becomes closer to the anti-resonant frequency, the pass rate of the RF signal between ports may be lowered.

At least one shunt bulk acoustic resonator (LR11, LR12, HR21, HR22) may be electrically shunt connected between at least one series bulk acoustic resonator (HR11, HR12, LR21, LR22) and a ground GND. As the frequency of the RF signal becomes closer to the resonant frequency, the pass rate of the RF signal toward the ground may be increased, and as the frequency of the RF signal becomes closer to the anti-resonant frequency, the pass rate of the RF signal toward the ground may be lowered.

The pass rate of the RF signal between ports may decrease as the pass rate of the RF signal toward the ground GND increases, and may increase as the pass rate of the RF signal toward the ground GND decreases.

For example, the pass rate of the RF signal between ports may be lowered as the RF signal becomes closer to the resonant frequency of the at least one shunt acoustic resonator LR11, LR12, HR21, and HR22 or becomes closer to the anti-resonant frequency of the at least one series acoustic resonator HR11, HR12, LR21, and LR22.

Since the anti-resonant frequency is higher than the resonant frequency, the bandpass filter may have a passband width formed of a lowest frequency corresponding to the resonant frequency of at least one shunt acoustic resonator (LR11, LR12) and a highest frequency corresponding to the anti-resonant frequency of at least one series acoustic resonator (HR11, HR12).

Since the anti-resonant frequency is higher than the resonant frequency, the notch filter may have a stopband width formed by a lowest frequency corresponding to the resonant frequency of at least one series acoustic resonator (LR21, LR22) and a highest frequency corresponding to the anti-resonant frequency of at least one shunt acoustic resonator (HR21, HR22).

Since at least a portion of the first passband may overlap at least a portion of the first stopband, the resonant frequency and/or anti-resonant frequency of at least one shunt acoustic resonator LR11 of the first bandpass filter and the resonant frequency and/or anti-resonant frequency of at least one series acoustic resonator LR21 of the first notch filter may be similar to each other, and the resonant frequency and/or anti-resonant frequency of the at least one series acoustic resonator HR11 of the first bandpass filter and the resonant frequency and/or anti-resonant frequency of at least one shunt acoustic resonator HR21 of the first notch filter may be similar to each other.

Since at least a portion of the second passband may overlap at least a portion of the second stopband, the resonant frequency and/or anti-resonant frequency of at least one shunt acoustic resonator LR12 of the second bandpass filter and the resonant frequency and/or anti-resonant frequency of at least one series acoustic resonator LR22 of the second notch filter may be similar to each other, and the resonant frequency and/or anti-resonant frequency of at least one series acoustic resonator HR12 of the second bandpass filter and/or the resonant frequency and/or anti-resonant frequency of the at least one shunt acoustic resonator HR22 of the second notch filter may be similar to each other.

The resonant frequency and/or the anti-resonant frequency being similar to each other indicates that the resonant frequency and/or the anti-resonant frequency of the corresponding acoustic resonators may be the same. Accordingly, in each of the first and second chips Chip1 and Chip2, which may include acoustic resonators having similar resonant frequencies and/or anti-resonant frequencies, the number of resonant frequencies and/or anti-resonant frequencies used may be reduced. When the number of resonant frequencies and/or anti-resonant frequencies is reduced, the process of forming a difference between resonant frequencies and/or anti-resonant frequencies between the plurality of bulk acoustic resonators included in the first and second chips Chip1 and Chip2 may be omitted. Therefore, the size and/or unit price of each of the first and second chips Chip1 and Chip2 may be further reduced, and the difference between the design value and the actual value of the resonant frequency and/or anti-resonance of a plurality of bulk acoustic resonators, which may occur due to process distribution of chips or the like, may also be reduced. Accordingly, in the case of the RF extractor 100e, not only may the size and/or unit cost be reduced, but filter performance (e.g., attenuation performance, insertion loss) may also be improved.

For example, a highest frequency fs_high and a lowest frequency fs_low of each of the first and second bandpass filters BPF and the first and second notch filters may be summarized in Table 1 below. In this case, each of the highest frequency fs_high and the lowest frequency fs_low may be a frequency belonging to a specific value (e.g., 10 dB) in the S-parameter between both ports of the filter.

TABLE 1

| | GPS/GLONASS(1559 [symbol] 1606 MHz) | | Wifi(2400 [symbol] 2481 MHz [symbol] | |
|---|---|---|---|---|
| | BPF(MHz [symbol] | Notch(MHz [symbol] | BPF(MHz) | Notch(MHz) |
| fs_high | 1581.5 | 1605.4 | 2449.8 | 2472.8 |
| fs_low | 1499 | 1483.5 | 2377.8 | 2334.8 |

[symbol]

indicates data missing or illegible when filed

For example, the difference between a lowest frequency of the first stopband (e.g., 1483.5 MHz) and a lowest frequency of the first passband (e.g., 1499 MHz), the difference between a lowest frequency of the first stopband (e.g., 1483.5 MHz) and a lowest frequency of the first passband (e.g., 1499 MHz), the difference between a lowest frequency of the second stopband (e.g., 2334.8 MHz) and a lowest frequency of the second passband (e.g., 2377.8 MHz), and the difference between a highest frequency of the first stopband (e.g., 1605.4 MHz) and a highest frequency of the first passband (e.g., 1581.5 MHz) may each be less than 100 MHz, in consideration of both the characteristic difference and the process distribution between the bandpass filter and the notch filter.

For example, when the resonant frequency and/or anti-resonant frequency of at least one shunt acoustic resonator LR11 of the first bandpass filter and the resonant frequency and/or anti-resonant frequency of the at least one series acoustic resonator LR21 of the first notch filter are designed to be substantially identical to each other, the difference between the lowest frequency (e.g., 1483.5 MHz) of the first stopband and the lowest frequency (e.g., 1499 MHz) of the first passband may be less than 100 MHz.

For example, when the resonant frequency and/or anti-resonant frequency of at least one series acoustic resonator HR11 of the first bandpass filter and the resonant frequency and/or anti-resonant frequency of at least one shunt acoustic resonator HR21 of the first notch filter are designed to be substantially identical to each other, the difference between the lowest frequency of the second stopband (e.g., 2334.8 MHz) and the lowest frequency (e.g., 2377.8 MHz) of the second passband may be less than 100 MHz.

For example, when the resonant frequency and/or anti-resonant frequency of at least one shunt acoustic resonator LR12 of the second bandpass filter and the resonant frequency and/or anti-resonant frequency of at least one series acoustic resonator LR22 of the second notch filter are designed to be substantially identical to each other, the difference between the highest frequency (e.g., 1605.4 MHz) of the first stopband and the highest frequency (e.g., 1581.5 MHz) of the first passband may be less than 100 MHz.

For example, when the resonant frequency and/or anti-resonant frequency of at least one series acoustic resonator HR12 of the second bandpass filter and the resonant frequency and/or anti-resonant frequency of at least one shunt acoustic resonator HR22 of the second notch filter are designed to be substantially identical to each other, the difference between the highest frequency (e.g., 2472.8 MHz) of the second stopband and the highest frequency (e.g., 2449.8 MHz) of the second passband may be less than 100 MHz.

On the other hand, the difference between the higher frequency (e.g., 1605.4 MHz), among the highest frequency of the first stopband and the highest frequency of the first passband, and the lower frequency (e.g., 2334.8 MHz), among the lowest frequency of the second stopband and the lowest frequency of the second passband, may exceed 100 MHz. Accordingly, the first bandpass filter and the first notch filter may be included in the first chip Chip1, and the second bandpass filter and the second notch filter may be included in the second chip Chip2.

For example, when portions of the resonant frequencies and/or anti-resonant frequencies of the bandpass filter and the notch filter are substantially equal to each other, the stopband may be formed slightly wider than the passband due to the difference in characteristics between the bandpass filter and the notch filter. For example, the bandwidth (e.g., 1483.5 MHz to 1605.4 MHz) of the first stopband may be wider than the bandwidth (e.g., 1499 MHz to 1581.5 MHz) of the first passband, and the bandwidth (e.g., 2334.8 MHz to 2472.8 MHz) of the second stopband may be wider than the bandwidth (e.g., 2377.8 MHz to 2449.8 MHz) of the second passband.

For example, each of the first passband and the first stopband may cover at least a portion of the frequency range of 1559 MHz or more and 1606 MHz or less, and each of the second passband and the second stopband may cover at least a portion of a frequency range of 2400 MHz or more and 2481 MHz or less.

On the other hand, the first inductor (L11, L21) may be electrically connected between at least one shunt acoustic resonator (LR11, HR21) and the ground GND in series, and the second inductor (L12, L22) may be electrically connected between at least one shunt acoustic resonator (LR12, HR22) and the ground GND in series.

The first inductor (L11, L21) may lower the anti-resonant frequency of at least one shunt acoustic resonator (LR11, HR21), and thus may be used to adjust the band of at least one of the first passband and the first stopband. The second inductor (L12, L22) may lower the anti-resonant frequency of at least one shunt acoustic resonator (LR12, HR22), and thus may be used to adjust the band of at least one of the second passband and the second stopband. Accordingly, the first and second chips Chip1 and Chip2 may more accurately adjust the bandwidth of each of the passband and the stopband, while using a structure designed such that portions of the resonant frequency and/or anti-resonant frequency of the bandpass filter and the notch filter are substantially the same as each other.

Referring to FIG. 3B, an RF extractor 100f may further include an impedance matching element MC2 electrically connected between first and second chips Chip1 and Chip2 including first and second notch filters, respectively.

Accordingly, since the electrical distance between the first and second notch filters may be increased, the first and second notch filters may be efficiently disposed in the first and second chips Chip1 and Chip2, respectively.

For example, the impedance matching element MC2 may have a third passband (e.g., 3G, 4G, and 5G cellular communications). Accordingly, the impedance matching element MC2 may pass at least an RF signal belonging to the third passband and may block an RF signal belonging to the remaining frequency.

In addition, a plurality of impedance matching elements MA11 and MA21 may be electrically connected between the first and second chips Chip1 and Chip2 and the shared antenna port ANT, and a plurality of impedance matching elements MB11, MB12 and MB22 may be electrically connected between the first and second chips Chip1 and Chip2 and the first, second, and third RF ports Port1, Port2 and Port3.

For example, each of the impedance matching elements MC2, MA11, MA21, MB11, MB12 and MB22 may have a structure in which one and the other of an inductor and a capacitor are connected by a series connection and a shunt connection, respectively.

On the other hand, since the first and second chips Chip1 and Chip2 may be MEMS chips or semiconductor chips, the bulk acoustic resonators HR11, LR11, HR21, LR21, HR12, LR12, HR22, and LR22 of FIGS. 3A and 3B may each be replaced by an acoustic resonator of another type (e.g., Surface Acoustic Wave) or a piezoelectric element (e.g., vibrator) of another type, depending on the applied design.

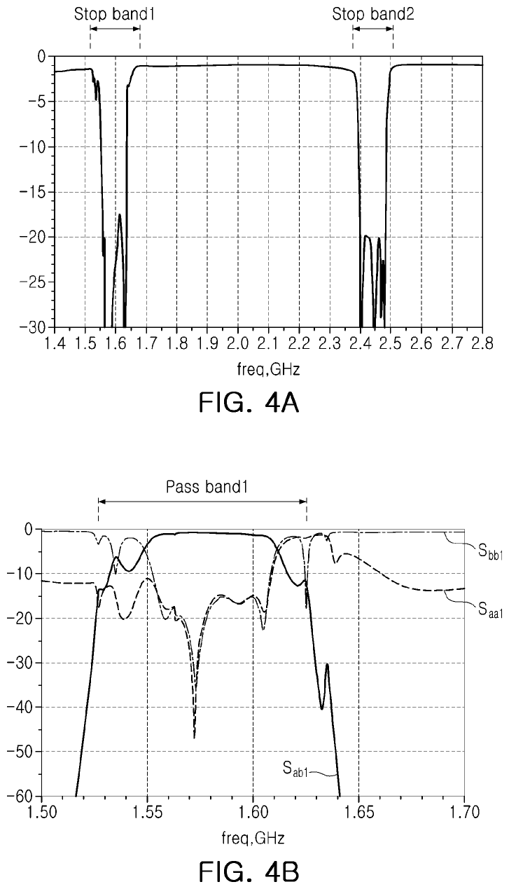

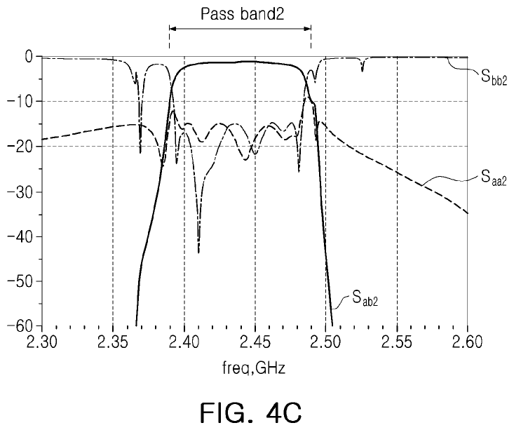

FIGS. 4A to 4C are graphs illustrating bands of filters included in an RF extractor, according to an example.

Referring to FIG. 4A, the S-parameter, in dB units, between the shared antenna port and the third port may indicate a first stopband (Stopband1) and a second stopband (Stopband2).

Referring to FIG. 4B, the S-parameter (S_{ab1}), in dB units, between the shared antenna port and the first port, the S-parameter (Sₐₐ₁) between the shared antenna ports in the first bandpass filter, and the S-parameter (S_{bb1}) between the first ports may represent a first passband (Passband1).

Referring to FIG. 4C, the S-parameter (S_{ab2}), in dB units, between the shared antenna port and the first port, the S-parameter (Sₐₐ₂), in dB units, between the shared antenna ports in the second bandpass filter, and the S-parameter (S_{bb2}), in dB units, between the second ports may represent a second passband (Passband2).

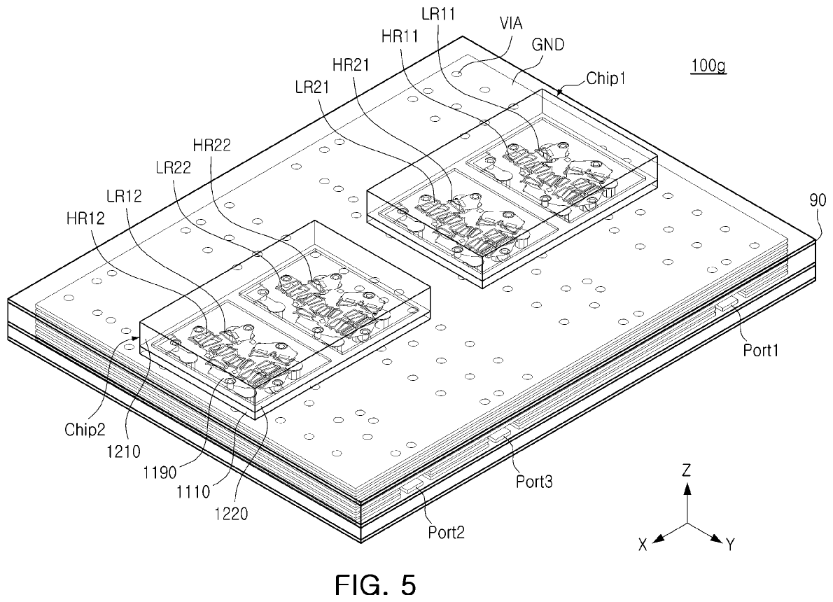

FIG. 5 is a perspective view illustrating an RF extractor, according to an example.

Referring to FIG. 5, an RF extractor 100g may include first and second chips Chip1 and Chip2, and the first chip Chip1 may include a plurality of first bulk acoustic resonators HR11, LR11, HR21, and LR21, and the second chip Chip2 may include a plurality of second bulk acoustic resonators HR12, LR12, HR22, and LR22.

The first bandpass filter may include portions HR11 and LR11 of the plurality of first bulk acoustic resonators, and the first notch filter may include other portions HR21 and LR21 of the plurality of first bulk acoustic resonators. The second bandpass filter may include portions HR12 and LR12 of the plurality of second bulk acoustic resonators, and the second notch filter may include the other portions HR22 and LR22 of the plurality of second bulk acoustic resonators. Accordingly, the first chip Chip1 may include a first bandpass filter and a first notch filter, and the second chip Chip2 may include a second bandpass filter and a second notch filter.

For example, the first and second chips Chip1 and Chip2 may be disposed (e.g., mounted or embedded) on a set substrate 90, and may be disposed to be spaced apart from each other. For example, the set substrate 90 may have a stacked structure in which a plurality of ground layers GND and a plurality of insulating layers are alternately stacked, may further include a via VIA vertically connecting the plurality of ground layers GND, and may be implemented as a printed circuit board (PCB).

For example, the set substrate 90 may be included in an electronic device, and may include a component (e.g., RFIC, a transceiver) electrically connected to the first and second chips Chip1 and Chip2 or the first, second, and third RF ports Port1, Port2, and Port3. Depending on the design, the set substrate 90 may further include an antenna.

Referring to FIG. 5, each of the first and second chips Chip1 and Chip2 may include at least one of a substrate 1110, a cap 1210, a bonding member 1220, and a metal layer 1190.

The substrate 1110 may have a cavity formed below the bulk acoustic resonators HR11, LR11, HR21, LR21, HR12, LR12, HR22, and LR22. In an example in which the bulk acoustic resonator is a solid mounted resonator (SMR), the bulk acoustic resonator may have a stacked structure in which heterogeneous layers having different acoustic impedances are alternately stacked.

The cap 1210 accommodates the bulk acoustic resonators HR11, LR11, HR21, LR21, HR12, LR12, HR22 and LR22, thereby protecting the bulk acoustic resonators HR11, LR11, HR21, LR21, HR12, LR12, HR22 and LR22 from the external environment. The cap 1210 may be formed in the form of a cover having an internal space in which the bulk acoustic resonators HR11, LR11, HR21, LR21, HR12, LR12, HR22 and LR22 are accommodated. For example, the cap 1210 may have a form in which a portion (e.g., the portion adjacent to the edge of the lower surface) of the surface (e.g., the lower surface) facing the substrate 1110 further protrudes toward the substrate 1110 than the other portion (e.g., the center of the lower surface). For example, the cap 1210 may have a U-shape when viewed in a horizontal direction.

The metal layer 1190 may connect between the bulk acoustic resonators HR11, LR11, HR21, LR21, HR12, LR12, HR22, and LR22, and may act as an electrical connection node.

The bonding member 1220 surrounds the bulk acoustic resonators HR11, LR11, HR21, LR21, HR12, LR12, HR22, and LR22 in the first direction (e.g., the Z direction), and may be disposed between the substrate 1110 and the cap 1210 and be bonded to the cap 1210. For example, the bonding member 1220 may have a eutectic bonding structure, and thus, may include a conductive ring. However, the bonding member 1220 is not limited to a eutectic bonding structure, and may be implemented as an anodic bonding structure or a melt bonding structure of a non-conductive material.

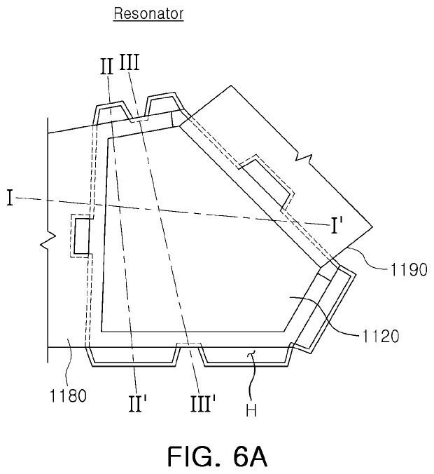

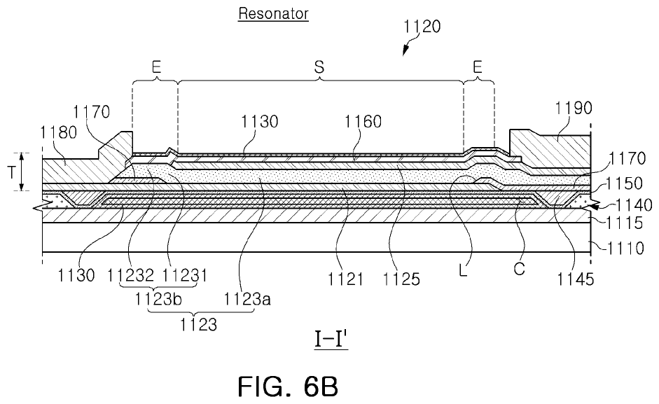

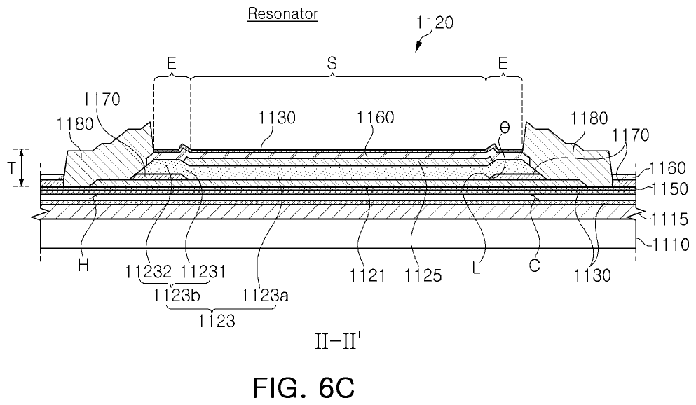

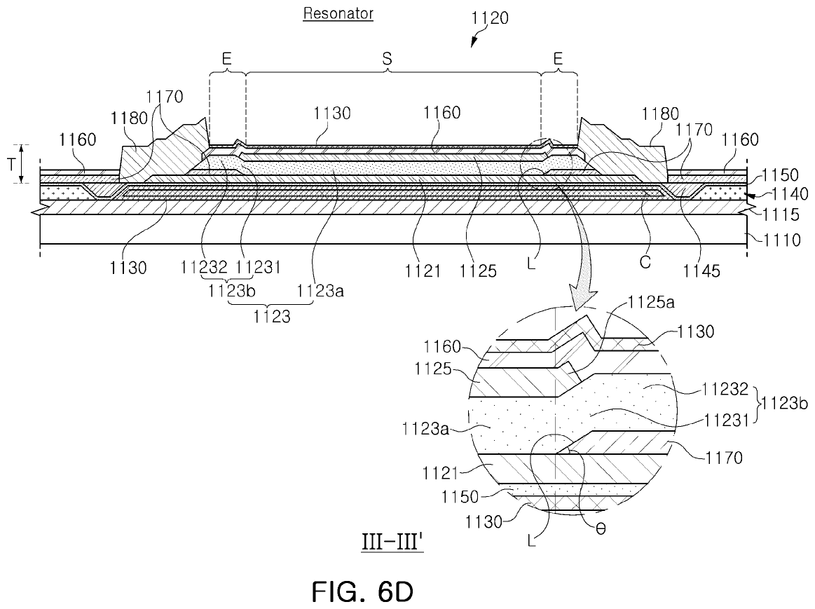

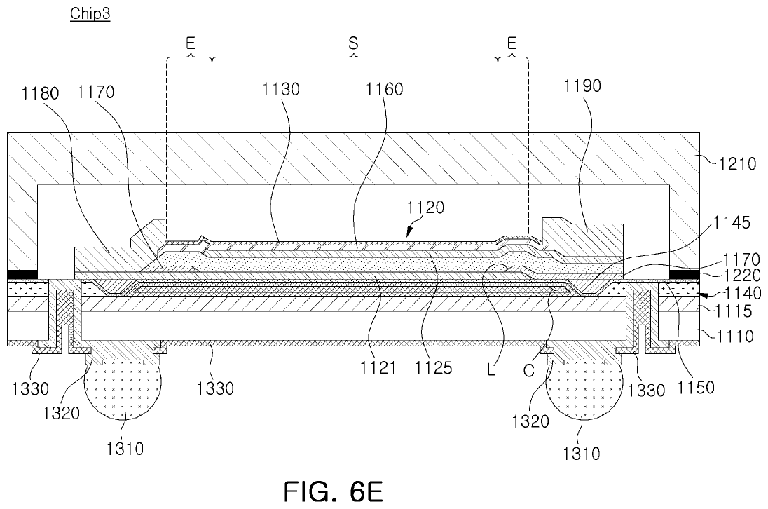

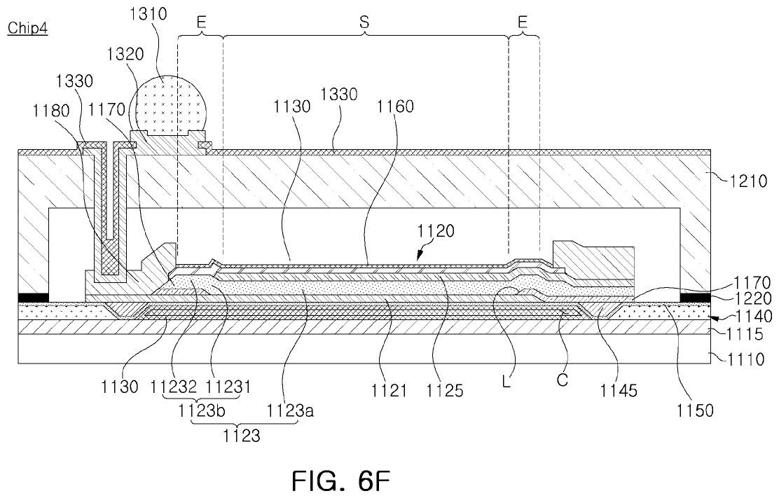

FIG. 6A is a plan view illustrating a detailed structure of a bulk acoustic resonator that may be included in a bulk acoustic resonator filter/package, according to an example. FIG. 6B is a cross-sectional view taken along line I-I′ in FIG. 6A. FIG. 6C is a cross-sectional view taken along line II-II′ of FIG. 6A. FIG. 6D is a cross-sectional view taken along line III-III′ of FIG. 6A.

Referring to FIGS. 6A to 6D, a bulk acoustic resonator may include a support substrate 1110, an insulating layer 1115, a resonant portion 1120, and a hydrophobic layer 1130.

The support substrate 1110 may be a silicon substrate. For example, a silicon wafer or a silicon on insulator (SOI) type substrate may be used as the support substrate 1110.

The insulating layer 1115 may be provided on the upper surface of the support substrate 1110 to electrically isolate the support substrate 1110 from the resonant portion 1120. In addition, the insulating layer 1115 may prevent the support substrate 1110 from being etched by the etching gas when a cavity C is formed in a process of manufacturing the bulk acoustic resonator.

The insulating layer 1115 may be formed of any one or any combination of any two or more of silicon dioxide (SiO₂), silicon nitride (Si₃N₄), aluminum oxide (Al₂O₃), and aluminum nitride (AlN), and may be formed by any one process among chemical vapor deposition, RF magnetron sputtering, and evaporation.

The support layer 1140 may be formed on the insulating layer 1115, and may be disposed around the cavity C and an etch stop portion 1145, in a form surrounding the cavity C and the etch stop portion 1145 inside thereof.

The cavity C is formed as an empty space, and may be formed by removing a portion of a sacrificial layer formed in the process of preparing the support layer 1140, and the support layer 1140 may be formed as a remaining portion of the sacrificial layer.

The support layer 1140 may be formed of a material such as polysilicon or a polymer that is easy to etch. However, the support layer 1140 is not limited to polysilicon or a polymer.

The etch stop portion 1145 may be disposed along the boundary of the cavity C. The etch stop portion 1145 may be provided to prevent etching from proceeding beyond the cavity region during the cavity C formation process.

A membrane layer 1150 is formed on the support layer 1140 and forms the upper surface of the cavity (C). Accordingly, the membrane layer 1150 may also be formed of a material that is not easily removed in the process of forming the cavity C.

For example, in an example in which a halide-based etching gas such as fluorine (F) or chlorine (CI) is used to remove a portion (e.g., a cavity region) of the support layer 1140, the membrane layer 1150 may be formed of a material having relatively low reactivity with the etching gas. In this case, the membrane layer 1150 may include either one or both of silicon dioxide (SiO₂) and silicon nitride (Si₃N₄).

In addition, the membrane layer 1150 may be formed of a dielectric layer including any one or any combination of any two or more of magnesium oxide (MgO), zirconium oxide (ZrO₂), aluminum nitride (AlN), lead zirconate titanate (PZT), gallium arsenide (GaAs), hafnium oxide (HfO₂), aluminum oxide (Al₂O₃), titanium oxide (TiO₂), and zinc oxide (ZnO), or may be formed of a metal layer including at least one of aluminum (Al), nickel (Ni), chromium (Cr), platinum (Pt), gallium (Ga), and hafnium (Hf). However, the memberane layer is not limited to the foregoing materials.

The resonant portion 1120 includes a first electrode 1121, a piezoelectric layer 1123, and a second electrode 1125. In the resonant portion 1120, the first electrode 1121, the piezoelectric layer 1123, and the second electrode 1125 are sequentially stacked from the bottom. Accordingly, in the resonant portion 1120, the piezoelectric layer 1123 may be disposed between the first electrode 1121 and the second electrode 1125.

Since the resonant portion 1120 is formed on the membrane layer 1150, the membrane layer 1150, the first electrode 1121, the piezoelectric layer 1123, and the second electrode 1125 are sequentially stacked on the support substrate 1110, thereby forming the resonant portion 1120.

The resonant portion 1120 may resonate the piezoelectric layer 1123 according to a signal applied to the first electrode 1121 and the second electrode 1125 to generate a resonant frequency and an anti-resonant frequency.

The resonant portion 1120 may include a central portion Sin which the first electrode 1121, the piezoelectric layer 1123, and the second electrode 1125 are stacked approximately flat, and an extended portion E in which an insertion layer 1170 is interposed between the first electrode 1121 and the piezoelectric layer 1123.

The central portion S is an area disposed on the center of the resonant portion 1120, and the extended portion E is an area disposed along the circumference of the central portion S. Therefore, the extended portion E is a region extending outwardly from the central portion (S), and may be a region formed in a continuous ring shape along the circumference of the central portion (S). However, if necessary, the extended portion E may alternatively be formed to have a discontinuous ring shape in which some regions are cut off.

Accordingly, as illustrated in FIG. 6B, in the cross-section of the resonant portion 1120 cut to traverse the central portion S, the extended portion E may be disposed on both ends of the central portion S, respectively. In addition, the insertion layer 1170 may be disposed on both sides of the extended portion E disposed on both ends of the central portion S.

The insertion layer 1170 may have an inclined surface L of which a thickness increases as the distance from the central portion S increases.

In the extended portion E, the piezoelectric layer 1123 and the second electrode 1125 may be disposed on the insertion layer 1170. Accordingly, the portions of the piezoelectric layer 1123 and the second electrode 1125 positioned in the extended portion E may have inclined surfaces along the shape of the insertion layer 1170.

On the other hand, the extended portion E may be defined to be included in the resonant portion 1120, and accordingly, resonance may also be formed in the extended portion E. However, the disclosure herein is not limited to such a configuration, and, depending on the structure of the extended portion E, resonance may not occur in the extended portion E and resonance may be formed only in the central portion S.

The first electrode 1121 and the second electrode 1125 may be formed of a conductor, and may be formed of, for example, gold, molybdenum, ruthenium, iridium, aluminum, platinum, titanium, tungsten, palladium, tantalum, chromium, nickel, or a metal including any one or any combination of any two or more of gold, molybdenum, ruthenium, iridium, aluminum, platinum, titanium, tungsten, palladium, tantalum, chromium, and nickel, However, the first and second electrodes are not limited to foregoing materials.

In the resonant portion 1120, the first electrode 1121 has a larger area than that of the second electrode 1125, and, on the first electrode 1121, a first metal layer 1180 is formed along the periphery of the first electrode 1121. Accordingly, the first metal layer 1180 may be disposed to be spaced apart from the second electrode 1125 by a predetermined distance, and may be disposed to surround the resonant portion 1120.

Since the first electrode 1121 is disposed on the membrane layer 1150, the first electrode 1121 is formed to be flat as a whole. On the other hand, the second electrode 1125 is disposed on the piezoelectric layer 1123, and thus, may have a curve corresponding to the shape of the piezoelectric layer 1123.

The first electrode 1121 may be used as one of an input electrode and an output electrode for inputting or outputting an electrical signal such as a radio frequency (RF) signal or the like.

The second electrode 1125 is disposed throughout an entirety of the central portion S, and is partially disposed in the extended portion E. Accordingly, the second electrode 1125 may include a portion disposed on a piezoelectric portion 1123a of the piezoelectric layer 1123 to be described in more detail later, and a portion disposed on a bent portion 1123b of the piezoelectric layer 1123.

In more detail, the second electrode 1125 may be disposed to cover the entire piezoelectric portion 1123a and a portion of an inclined portion 11231 of the piezoelectric layer 1123. Therefore, the portion of the second electrode (1125a in FIG. 6D) disposed in the extended portion E has a smaller area than that of the inclined surface of the inclined portion 11231, and the portion of the second electrode 1125 in the resonant portion 1120 may be formed to have the area smaller than that of the piezoelectric layer 1123.

Accordingly, as illustrated in FIG. 6B, in a cross-section in which the resonant portion 1120 is cut to traverse the central portion S, the end of the second electrode 1125 is disposed in the extended portion E. In addition, the end of the second electrode 1125 disposed in the extended portion E may be disposed such that at least a portion thereof overlaps the insertion layer 1170. In this case, overlap indicates that when the second electrode 1125 is projected on the plane on which the insertion layer 1170 is disposed, the shape of the second electrode 1125 projected on the plane overlaps the insertion layer 1170.

The second electrode 1125 may be used as one of the input electrode and the output electrode for inputting or outputting an electrical signal such as a radio frequency (RF) signal. For example, when the first electrode 1121 is used as the input electrode, the second electrode 1125 may be used as the output electrode, and when the first electrode 1121 is used as the output electrode, the second electrode 1125 may be used as the input electrode.

On the other hand, as illustrated in FIG. 6D, for example, when the end of the second electrode 1125 is positioned on the inclined portion 11231 of the piezoelectric layer 1123, in the case of the acoustic impedance of the resonant portion 1120, since the local structure is formed in a rarefaction/compression/rarefaction/compression structure from the central portion S, a reflection interface that reflects the lateral wave toward the inside of the resonant portion 1120 may be increased. Accordingly, since most of the lateral waves may not escape to the outside of the resonant portion 1120 and are reflected into the resonant portion 1120, the performance of the bulk acoustic resonator may be improved.

The piezoelectric layer 1123 generates a piezoelectric effect that converts electrical energy into mechanical energy in the form of acoustic waves, and may be formed on the first electrode 1121 and the insertion layer 1170.

Zinc oxide (ZnO), aluminum nitride (AlN), doped aluminum nitride, lead zirconate titanate, quartz, or the like may be selectively used as a material of the piezoelectric layer 1123. In the case of doped aluminum nitride, a rare earth metal, a transition metal, or an alkaline earth metal may be further included. The rare earth metal may include any one or any combination of any two or more of scandium (Sc), erbium (Er), yttrium (Y), and lanthanum (La). The transition metal may include any one or any combination of any two or more of hafnium (Hf), titanium (Ti), zirconium (Zr), tantalum (Ta), and niobium (Nb). The alkaline earth metal may include magnesium (Mg). The content of elements doped on aluminum nitride (AlN) may be in the range of 0.1 to 30 at %.

The piezoelectric layer may be formed by doping aluminum nitride (AlN) with scandium (Sc). In this case, the piezoelectric constant may be increased to increase the kt² of the bulk acoustic resonator.

The piezoelectric layer 1123 may include the piezoelectric portion 1123a disposed in the central portion S, and the bent portion 1123b disposed in the expanded portion E.

The piezoelectric portion 1123a is a part directly stacked on the upper surface of the first electrode 1121. Accordingly, the piezoelectric portion 1123a may be interposed between the first electrode 1121 and the second electrode 1125, and may be formed in a flat shape together with the first electrode 1121 and the second electrode 1125.

The bent portion 1123b may be a region extending outwardly from the piezoelectric portion 1123a and positioned within the extended portion E.

The bent portion 1123b is disposed on the insertion layer 1170, and may be formed in a shape in which an upper surface thereof is raised along the shape of the insertion layer 1170. Accordingly, the piezoelectric layer 1123 is bent at the boundary between the piezoelectric portion 1123a and the bent portion 1123b, and the bent portion 1123b may be raised to correspond to the thickness and shape of the insertion layer 1170.

The bent portion 1123b may be include an inclined portion 11231 and an extended portion 11232.

The inclined portion 11231 is a portion formed to be inclined along an inclined surface L of the insertion layer 1170. In addition, the extended portion 11232 is a portion extending outwardly from the inclined portion 11231.

The inclined portion 11231 may be formed parallel to the inclined surface L of the insertion layer 1170, and an inclination angle of the inclined portion 11231 may be formed to be the same as an inclination angle of the inclined surface L of the insertion layer 1170.

The insertion layer 1170 may be disposed along a surface formed by the membrane layer 1150, the first electrode 1121, and the etch stop portion 1145. Accordingly, the insertion layer 1170 may be partially disposed in the resonant portion 1120, and may be disposed between the first electrode 1121 and the piezoelectric layer 1123.

The insertion layer 1170 may be disposed around the central portion S to support the bent portion 1123b of the piezoelectric layer 1123. Accordingly, the bent portion 1123b of the piezoelectric layer 1123 may be divided into the inclined portion 11231 and the extended portion 11232 according to the shape of the insertion layer 1170.

The insertion layer 1170 may be disposed in an area except for the central portion S. For example, the insertion layer 1170 may be disposed in the entire region except for the central portion S, on the support substrate 1110, or may be disposed in a partial region excluding the central portion S.

The insertion layer 1170 may be formed to have a thickness that increases as the distance from the central portion S increases. Therefore, the insertion layer 1170 may be formed to have the inclined surface L in which a side surface thereof disposed adjacent to the central portion S has a predetermined inclination angle θ. The inclination angle θ of the inclined surface L may be formed in a range of 5° to 70°.

The inclined portion 11231 of the piezoelectric layer 1123 may be formed along the inclined surface L of the insertion layer 1170 and may be formed at the same inclination angle as that of the inclined surface L of the insertion layer 1170. Accordingly, the inclination angle of the inclined portion 11231 may be formed in a range of 5° to 70°, similarly to the inclined surface L of the insertion layer 1170. This configuration may also be equally applied to the portion of the second electrode 1125 stacked on the inclined surface L of the insertion layer 1170.

The insertion layer 1170 may be formed of a dielectric such as silicon oxide (SiO₂), aluminum nitride (AlN), aluminum oxide (Al₂O₃), silicon nitride (Si₃N₄), magnesium oxide (MgO), zirconium oxide (ZrO₂), lead zirconate titanate (PZT), gallium arsenide (GaAs), hafnium oxide (HfO₂), titanium oxide (TiO₂), zinc oxide (ZnO), or the like, but may be formed of a material different from that of the piezoelectric layer 1123.

In addition, the insertion layer 1170 may be implemented with a metal material. For example, when the bulk acoustic resonator is used for 5G communication, since a lot of heat is generated in the resonant portion, smoothly radiating the heat generated in the resonant portion 1120 is required. To this end, the insertion layer 1170 may be formed of an aluminum alloy material containing scandium (Sc).

The resonant portion 1120 may be spaced apart from the support substrate 1110 through the cavity C, which may be formed as an empty space.

The cavity C may be formed by supplying an etching gas (or an etching solution) to an inlet hole (H in FIG. 6A) to remove a portion of the support layer 1140 during the process of manufacturing the bulk acoustic resonator.

Accordingly, the cavity C may be configured as a space in which the upper surface (ceiling surface) and the side surface (wall surface) are constituted by the membrane layer 1150 and the bottom surface is formed by the support substrate 1110 or the insulating layer 1115. On the other hand, the membrane layer 1150 may also be formed only on the upper surface (ceiling surface) of the cavity C according to the order of the manufacturing method.

A protective layer 1160 may be disposed along a surface of the bulk acoustic resonator to protect the bulk acoustic resonator from the outside thereof. The protective layer 1160 may be disposed along a surface formed by the second electrode 1125 and the bent portion 1123b of the piezoelectric layer 1123.

The protective layer 1160 may be partially removed for frequency control in a final process during the manufacturing process. For example, the thickness of the protective layer 1160 may be adjusted through frequency trimming during a manufacturing process.

To this end, the protective layer 1160 may include any one of silicon dioxide (SiO₂), silicon nitride (Si₃N₄), magnesium oxide (MgO), zirconium oxide (ZrO₂), aluminum nitride (AlN), lead lirconate titanate (PZT), gallium arsenic (GaAs), hafnium oxide (HfO₂), aluminum oxide (Al₂O₃), titanium oxide (TiO₂), zinc oxide (ZnO), amorphous silicon (a-Si), and polycrystalline silicon (p-Si), which are suitable for frequency trimming, but is not limited thereto.

The first electrode 1121 and the second electrode 1125 may extend outwardly of the resonant portion 1120. In addition, a first metal layer 1180 and a second metal layer 1190 may be respectively disposed on the upper surface of the extended portion.

The first metal layer 1180 and the second metal layer 1190 may be formed of any one material of gold (Au), a gold-tin (Au—Sn) alloy, copper (Cu), a copper-tin (Cu—Sn) alloy, aluminum (Al), and an aluminum alloy. In this case, the aluminum alloy may be an aluminum-germanium (Al—Ge) alloy or an aluminum-scandium (Al—Sc) alloy.

The first metal layer 1180 and the second metal layer 1190 may function as connection wiring electrically connecting the first and second electrodes 1121 and 1125 of the bulk acoustic resonator to electrodes of other volumetric acoustic resonators disposed adjacently to the bulk acoustic resonator, on the support substrate 1110.

At least a portion of the first metal layer 1180 may be in contact with the protective layer 1160 and may be bonded to the first electrode 1121.

Also, in the resonant portion 1120, the first electrode 1121 may have a larger area than the second electrode 1125, and the first metal layer 1180 may be formed on a peripheral portion of the first electrode 1121.

Accordingly, the first metal layer 1180 may be disposed along the circumference of the resonant portion 1120, and may thus be disposed to surround the second electrode 1125. However, the disclosure herein is not limited to this configuration.

A hydrophobic layer 1130 may be disposed on the surface of the protective layer 1160 and the inner wall of the cavity C. Since the hydrophobic layer 1130 serves to suppress the adsorption of water and a hydroxyl group (OH group), frequency fluctuations may be significantly reduced, and thus the resonator performance may be uniformly maintained.

The hydrophobic layer 1130 may be formed of a self-assembled monolayer (SAM) forming material, rather than a polymer. If the hydrophobic layer 1130 were formed of a polymer, the mass of the polymer may affect the resonant portion 1120. However, since the hydrophobic layer 1130 is formed of the self-assembled monolayer, fluctuations in the resonant frequency of the bulk acoustic resonator may be significantly reduced. In addition, the thickness of the hydrophobic layer 1130 according to the position thereof in the cavity C may be uniformly formed.

The hydrophobic layer 1130 may be formed by vapor-depositing a precursor that may have hydrophobicity. In this case, the hydrophobic layer 1130 may be deposited as a monolayer having a thickness of 100 Å or less (e.g., several A to several tens of A). A material having a contact angle with water of 90° or more after deposition may be used as the precursor having hydrophobicity. For example, the hydrophobic layer 1130 may contain a fluorine (F) component, and may include fluorine (F) and silicon (Si). For example, a fluorocarbon having a silicon head may be used, but the material of the hydrophobic layer 1130 is not limited to a fluorocarbon having a silicon head.

To improve the adhesion between the self-assembled monolayer constituting the hydrophobic layer 1130 and the protective layer 1160, a bonding layer (not illustrated) may be formed on the surface of the protective layer, prior to forming the hydrophobic layer 1130.

The bonding layer may be formed by vapor-depositing a precursor having a hydrophobicity functional group on the surface of the protective layer 1160.

The precursor used for depositing the bonding layer may be hydrocarbon having a silicon head or siloxane having a silicon head, but is not limited thereto.

The hydrophobic layer 1130 is formed after the first metal layer 1180 and the second metal layer 1190 are formed, and thus, may be formed along the surfaces of the protective layer 1160, the first metal layer 1180, and the second metal layer 1190.

In FIGS. 6B to 6D, an example in which the hydrophobic layer 1130 is not disposed on the surfaces of the first metal layer 1180 and the second metal layer 1190 is illustrated, but the disclosure is not limited to such a configuration. For example, the hydrophobic layer 1130 may also be disposed on the surfaces of the first metal layer 1180 and the second metal layer 1190, if necessary.

In addition, the hydrophobic layer 1130 may be disposed on the inner surface of the cavity C as well as the upper surface of the protective layer 1160.

The hydrophobic layer 1130 may be formed on the entirety of the inner wall forming the cavity C. Accordingly, the hydrophobic layer 1130 may also be formed on the lower surface of the membrane layer 1150 forming the lower surface of the resonant portion 1120. In this case, adsorption of a hydroxyl group to the lower portion of the resonant portion 1120 may be prevented.

Adsorption of the hydroxyl group may occur not only on the protective layer 1160 but also in the cavity C. Therefore, to significantly reduce mass loading and consequent frequency drop due to hydroxyl group adsorption, the hydroxyl group adsorption may be prevented not only on the protective layer 1160 but also on the upper surface of the cavity C (the lower surface of the membrane layer 1150), which is the lower surface of the resonant portion 1120.

In addition, when the hydrophobic layer 1130 is formed on the upper/lower surface or the side surface of the cavity C, in a wet process or a cleaning process after the cavity C is formed, an effect of suppressing a stiction phenomenon in which the resonant portion 1120 sticks to the insulating layer 1115 due to surface tension may be provided.

Although the example of forming the hydrophobic layer 1130 on the entire inner wall of the cavity (C) is illustrated, the disclosure is not limited to this example. Various modifications are possible, such as forming the hydrophobic layer only on the upper surface of the cavity C, or forming the hydrophobic layer 1130 only on at least a portion of the lower surface and side surfaces of the cavity (C).

On the other hand, a thickness T of the bulk acoustic resonator may be determined based on a designed resonant frequency and/or anti-resonant frequency. For example, the thickness T may be measured by analysis using at least one of Transmission Electron Microscopy (TEM), Atomic Force Microscope (AFM), Scanning Electron Microscope (SEM), an optical microscope, and a surface profiler.

FIGS. 6E and 6F are cross-sectional views illustrating a structure electrically connecting the inside and the outside of a chip that may be included in an RF extractor, according to examples.

Referring to FIGS. 6E and 6F, chips Chip3 and Chip4 may further include at least one of the hydrophobic layer 1130, a bump 1310, a connection pattern 1320, and a hydrophobic layer 1330.

The hydrophobic layer 1130 is disposed between the resonant portion 1120 and the cap 1210, and may have a relatively more hydrophobic properties than those of the cap 1210. Accordingly, the adsorption of organic matter, moisture, or the like, which may be generated in the process of forming the bonding member 1220, to the resonant portion 1120 may be reduced. Thus, the characteristics of the resonant portion 1120 may be further improved. For example, the hydrophobic layer 1130 may be formed on the upper surface of the resonant portion 1120.

Referring to FIG. 6E, at least a portion of the connection pattern 1320 may penetrate through the substrate 1110, may be electrically connected to either one or both of the first and second electrodes 1121 and 1125, and may be in contact with the hydrophobic layer 1330.

Accordingly, the resonant portion 1120 may be electrically connected to the outside of a bulk acoustic resonator package 100f.

The hydrophobic layer 1330 may be disposed on a surface (e.g., a lower surface) of the substrate 1110 opposite to a surface (e.g., an upper surface) thereof facing the cap 1210 and may have relatively more hydrophobic characteristics than those of the substrate 1110. Accordingly, the adsorption of organic matter, moisture, or the like that may occur during the formation process of the bonding member 1220 to the connection pattern 1320 may be reduced. Thus, a transmission loss in the connection pattern 1320 may be further reduced.

Referring to FIG. 6F, at least a portion of the connection pattern 1320 may penetrate the cap 1210, may be electrically connected to at least one of the first and second electrodes 1121 and 1125, and may be in contact with the hydrophobic layer 1330. Accordingly, the resonant portion 1120 may be electrically connected to the outside of a bulk acoustic resonator package 100g.

The hydrophobic layer 1330 may be disposed on a surface (e.g., an upper surface) of the cap 1210 opposite to a surface (e.g., a lower surface) thereof facing the substrate 1110, and may have relatively more hydrophobic characteristics than those of the cap 1210. Accordingly, adsorption of organic matter, moisture, or the like that may occur in the process of forming the bonding member 1220 to the connection pattern 1320 may be reduced. Thus, a transmission loss in the connection pattern 1320 may be further reduced.

For example, in a state in which a hole is perforated in a portion of the substrate 1110 and/or the cap 1210, the connection pattern 1320 may be formed by a process of depositing, coating, or filling a conductive metal (e.g., gold, copper, a titanium (Ti)-copper (Cu) alloy, or the like) on a sidewall of the hole.

On the other hand, a process of forming a hole in a portion of the substrate 1110 and/or the cap 1210 may be omitted. For example, the resonant portion 1120 may be provided with an electrical connection path by wire bonding.

The bumps 1310 may have a structure supporting the chips Chip3 and Chip4 such that the chips Chip3 and Chip4 may be mounted on the lower external PCB. For example, a portion of the connection pattern 1320 may have a pad shape in contact with the bump 1310.

An RF extractor according to examples disclosed herein may have a reduced size or may be inexpensively implemented while securing filter performance (e.g., attenuation performance, insertion loss, and the like) or efficiently using the bandwidth of a shared antenna.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A radio frequency (RF) extractor, comprising:
a first bandpass filter electrically connected between a shared antenna port and a first RF port, disposed in a first chip, and having a first passband;
a second bandpass filter electrically connected between the shared antenna port and a second RF port, and disposed in a second chip, and having a second passband;
a first notch filter electrically connected to the shared antenna port, disposed in the first chip, and having a first stopband partially overlapping the first passband; and
a second notch filter electrically connected to the shared antenna port, disposed in the second chip, and having a second stopband partially overlapping the second passband.

2. The RF extractor of claim 1, wherein the first and second notch filters are electrically connected to each other in series between the shared antenna port and a third RF port.

3. The RF extractor of claim 2, further comprising an impedance matching element electrically connected between the first and second notch filters.

4. The RF extractor of claim 3, wherein the impedance matching element has a third passband.

5. The RF extractor of claim 1, wherein the first chip comprises a plurality of first bulk acoustic resonators, and
wherein the second chip comprises a plurality of second bulk acoustic resonators.

6. The RF extractor of claim 5, wherein the first bandpass filter and the first notch filter comprise one portion and another portion of the plurality of first bulk acoustic resonators, respectively, and
wherein the second bandpass filter and the second notch filter comprise one portion and another portion of the plurality of second bulk acoustic resonators, respectively.

7. The RF extractor of claim 6, wherein either one or both of the first bandpass filter and the first notch filter further comprises a first inductor electrically connected between at least one of the plurality of first bulk acoustic resonators and a ground in series, and
wherein either one or both of the second bandpass filter and the second notch filter further comprises a second inductor electrically connected between at least one of the plurality of second bulk acoustic resonators and the ground in series.

8. The RF extractor of claim 1, wherein a difference between a lowest frequency of the first stopband and a lowest frequency of the first passband, a difference between a lowest frequency of the second stopband and a lowest frequency of the second passband, a difference between a highest frequency of the first stopband and a highest frequency of the first passband, and a difference between a highest frequency of the second stopband and a highest frequency of the second passband are each less than 100 MHz, and
wherein a difference between a higher frequency, among the highest frequency of the first stopband and the highest frequency of the first passband, and a lower frequency, among the lowest frequency of the second stopband and the lowest frequency of the second passband, exceeds 100 MHz.

9. The RF extractor of claim 1, wherein each of the first passband and the first stopband covers at least a portion of a frequency range of 1559 MHz to 1606 MHz, and
wherein each of the second passband and the second stopband covers at least a portion of a frequency range of 2400 MHz to 2481 MHz.

10. The RF extractor of claim 1, wherein a bandwidth of the first stopband is wider than a bandwidth of the first passband, and
wherein a bandwidth of the second stopband is wider than a bandwidth of the second passband.

11. A radio frequency (RF) extractor, comprising:
a first bandpass filter electrically connected between a shared antenna port and a first RF port and having a first passband;
a second bandpass filter electrically connected between the shared antenna port and a second RF port and having a second passband;
a first notch filter electrically connected between the shared antenna port and a third RF port and having a first stopband partially overlapping the first passband; and
a second notch filter electrically connected between the shared antenna port and the third RF port and having a second stopband partially overlapping the second passband,
wherein the first and second notch filters are electrically connected to each other between the shared antenna port and the third RF port in series.

12. The RF extractor of claim 11, further comprising an impedance matching element electrically connected between the first and second notch filters.

13. The RF extractor of claim 12, wherein the impedance matching element has a third passband.

14. The RF extractor of claim 11, wherein the first bandpass filter and the first notch filter comprise one portion and another portion of a plurality of first bulk acoustic resonators, respectively, and
wherein the second bandpass filter and the second notch filter comprise one portion and another portion of a plurality of second bulk acoustic resonators, respectively.

15. The RF extractor of claim 11, wherein a difference between a lowest frequency of the first stopband and a lowest frequency of the first passband, a difference between a lowest frequency of the second stopband and a lowest frequency of the second passband, a difference between a highest frequency of the first stopband and a highest frequency of the first passband, and a difference between a highest frequency of the second stopband and a highest frequency of the second passband are each less than 100 MHz, and
a difference between a higher frequency, among the highest frequency of the first stopband and the highest frequency of the first passband, and a lower frequency, among the lowest frequency of the second stopband and the lowest frequency of the second passband, exceeds 100 MHz.

16. The RF extractor of claim 11, wherein each of the first passband and the first stopband covers at least a portion of a frequency range of 1559 MHz to 1606 MHz,
wherein each of the second passband and the second stopband covers at least a portion of a frequency range of 2400 MHz to 2481 MHz,
wherein a bandwidth of the first stopband is wider than a bandwidth of the first passband, and
wherein a bandwidth of the second stopband is wider than a bandwidth of the second passband.

17. An electronic device, comprising:
a first chip including:
a first bandpass filter electrically connected between a shared antenna port and a first RF port, the first bandpass filter having a first passband corresponding to a GPS communication standard; and
a first notch filter electrically connected to the shared antenna port and having a first stopband partially overlapping the first passband; and
a second chip including:
a second bandpass filter electrically connected between the shared antenna port and a second RF port, the second bandpass filter having a second passband corresponding to a W-Fi communication standard; and
a second notch filter electrically connected to the shared antenna port and having a second stopband partially overlapping the second passband.

18. The electronic device of claim 17, further comprising an impedance matching element having a third passband and connected between the first and second notch filters,
wherein the first and second notch filters are electrically connected to each other between the shared antenna port and a third RF port.

19. The electronic device of claim 17, wherein the first bandpass filter and the first notch filter comprise portions of a plurality of first bulk acoustic resonators, respectively, and
wherein the second bandpass filter and the second notch filter comprise portions of a plurality of second bulk acoustic resonators, respectively.

20. The electronic device of claim 17, wherein a bandwidth of the first stopband is wider than a bandwidth of the first passband, and
wherein a bandwidth of the second stopband is wider than a bandwidth of the second passband.
